(19) United States
(12) Patent Application Publication
(10) Pub. No.: US 2022/0224357 A1
(43) Pub. Date: Jul. 14, 2022

(54) DATA PROCESSING METHOD AND DECODER

(71) Applicant: Huawei Technologies Co., Ltd., Shenzhen (CN)

(72) Inventors: Yuanxiang ZHANG, Shanghai (CN); Yang ZHOU, Shanghai (CN)

(21) Appl. No.: 17/656,945

(22) Filed: Mar. 29, 2022

Related U.S. Application Data
(63) Continuation of application No. PCT/CN2020/104335, filed on Jul. 24, 2020.

(30) Foreign Application Priority Data
Sep. 30, 2019 (CN) 201910945369.2

(51) Int. Cl. H03M 13/11

(52) U.S. Cl. CPC H03M 13/1168; H03M 13/1145; H03M 13/112; H03M 13/1177

(57) ABSTRACT

A computer-implemented method includes: receiving a code word sequence whose digit quantity is n; determining a check matrix of an order m×n, where a base matrix of the check matrix is a matrix of an order m_{b}×n_{b}; setting L variable nodes based on the base matrix, where L is greater than or equal to a quantity of values not equal to 1 in a row with a maximum quantity of values not equal to −1 in the base matrix; separately mapping valid submatrices in each layer of a check node to the L variable nodes; sending, to each of the L variable nodes that were mapped, data corresponding to each valid submatrix in each layer of the check matrix; and performing a corresponding operation in a layered normalized min-sum decoding algorithm by the L variable nodes using the data that was sent.

### CROSS-REFERENCE TO RELATED APPLICATIONS

This application is a continuation of International Application No. PCT/CN2020/104335, filed on Jul. 24, 2020, which claims priority to Chinese Patent Application No. 201910945369.2, filed on Sep. 30, 2019. The disclosures of the aforementioned applications are hereby incorporated by reference in their entireties.

### TECHNICAL FIELD

This application relates to the communications field, and in particular, to a data processing method and a decoder.

### BACKGROUND

Quasi-cyclic low-density parity-check (QC-LDPC) is a common type of LDPC code, which has a feature of a flexible structure, and may be used as a check code, and is usually represented as a check matrix. Specifically, a transmit end may encode, by using a preset check matrix, an information sequence that is to be sent, to generate a code word sequence, and send the code word sequence to a receive end. After receiving a code word sequence code, the receive end may decode the code word sequence by using a same check matrix to obtain the information sequence.

A commonly used decoding algorithm includes a layered decoding algorithm (LDA). During implementation of the LDA, a check base matrix is vertically divided into several layers based on rows of the base matrix, and is used layer by layer during decoding, to update a code word sequence. Each time a layer is used, an obtained new sequence is used as an input value, and the new sequence is updated by using a next layer of the check matrix, until a last layer of the check matrix is used. An obtained latest sequence is used as an information sequence.

It is assumed that the check matrix is a matrix of an order m×n, an extension factor of the base matrix of the check matrix is Z, and the base matrix is a matrix of an order m_{b}×n_{b}, where m_{b}=m/Z and n_{b}=n/Z. Currently, in terms of hardware cooperation, the LDA is mainly implemented by using a row-level parallel solution. In the row-level parallel solution, n_{b} variable nodes and Z check nodes need to be disposed, and the code word sequence is calculated by using a row in each layer of the check matrix. If a check matrix is relatively large, relatively more hardware resources are required, and costs are relatively high.

### SUMMARY

Embodiments of this application provide a data processing method and a decoder, to decode a code word sequence.

According to a first aspect, this application provides a data processing method. The method uses a decoding algorithm based on layered normalized min-sum and includes: receiving a code word sequence whose digit quantity is n, where n is a positive integer; determining a check matrix of an order m×n, where a base matrix of the check matrix is a matrix of an order m_{b}×n_{b}, m_{b} is equal to m/Z, n_{b} is equal to n/Z, Z is an extension factor of the base matrix, both m and Z are positive integers, and Z is divisible by both m and n; setting L variable nodes based on the base matrix, where L is greater than or equal to a quantity of values not equal to −1 in a row with a maximum quantity of values not equal to −1 in the base matrix, and the value not equal to −1 in the base matrix represents a non-zero submatrix of an order Z×Z in the check matrix; separately mapping valid submatrices in each layer of the check node to the L variable nodes, where different valid submatrices are mapped to different variable nodes, the valid submatrix is a submatrix represented by the value not equal to −1 in the base matrix, and a layer of the check node is a submatrix represented by a row of the base matrix; sending, to each of the L mapped variable nodes, data corresponding to each valid submatrix in each layer of the check matrix; and performing a corresponding operation in the layered normalized min-sum decoding algorithm by the L variable nodes by using the received data.

In some embodiments, L is equal to the quantity of values not equal to −1 in the row with a maximum quantity of values not equal to −1 in the base matrix.

Therefore, the layered normalized min-sum decoding algorithm may be performed by using a relatively small quantity of L variable nodes, and relatively few hardware resources are required, thereby effectively reducing costs.

In some embodiments, the determining a check matrix of an order m×n includes: determining the base matrix of an order m_{b}×n_{b} based on n, Z, and a preset matrix having a raptor-like structure; and extending the base matrix to obtain the check matrix of an order m×n. Therefore, the check matrix may be determined based on a requirement.

In some embodiments, the method further includes:

setting P check nodes, where P is a positive integer less than Z, each layer of the check matrix is divided into ceiling (Z/P) sublayers, ceiling ( ) is a rounding up function, and each sublayer includes rows not exceeding P rows of the check matrix; and separately making rows in each sublayer of each layer of the check matrix to be corresponding to the P check nodes, where different rows correspond to different check nodes; receiving data by using the P check nodes; and performing a corresponding operation in the layered normalized min-sum decoding algorithm on the data by using a corresponding row in each sublayer. Therefore, relatively few check nodes may be disposed, and relatively few hardware resources are required, thereby effectively reducing costs.

In some embodiments, after the setting P check nodes, the method further includes:

determining an offset value, and adjusting, based on the offset value, a sequence of using sublayers of a layer of the check matrix. Therefore, a proper offset value may be found to perform transformation on a matrix, and impact of a conflict between reading and writing on a throughput rate of a decoder may be alleviated to a specific extent by using a transformed matrix.

According to a second aspect, this application provides a decoder. The decoder uses a decoding algorithm based on layered normalized min-sum and includes: a transceiver module, configured to receive a code word sequence whose digit quantity is n, where n is a positive integer; and a processing device , configured to determine a check matrix of an order m×n, where a base matrix of the check matrix is a matrix of an order m_{b}×n_{b}, m_{b} is equal to m/Z, n_{b} is equal to n/Z, Z is an extension factor of the base matrix, both m and Z are positive integers, and Z is divisible by both m and n. The processing device is further configured to set L variable nodes based on the base matrix, where L is greater than or equal to a quantity of values not equal to −1 in a row with a maximum quantity of values not equal to −1 in the base matrix, and the value not equal to −1 in the base matrix represents a non-zero submatrix of an order Z×Z in the check matrix. The processing device is further configured to separately mapping valid submatrices in each layer of the check node to the L variable nodes, where different valid submatrices are mapped to different variable nodes, the valid submatrix is a submatrix represented by the value not equal to −1 in the base matrix, and a layer of the check node is a submatrix represented by a row of the base matrix. The processing device is further configured to send, to each of the L mapped variable nodes, data corresponding to each valid submatrix in each layer of the check matrix. The L variable nodes are configured to perform a corresponding operation in the layered normalized min-sum decoding algorithm by using the received data.

In some embodiments, the processing device is configured to: determine the base matrix of an order m_{b}×n_{b} based on n, Z, and a preset matrix having a raptor-like structure; and extend the base matrix to obtain the check matrix of an order m×n.

In some embodiments, the processing device is further configured to set P check nodes, where P is a positive integer less than Z, each layer of the check matrix is divided into ceiling (Z/P) sublayers, ceiling ( ) is a rounding up function, and each sublayer includes rows not exceeding P rows of the check matrix. The decoder further includes P check nodes, configured to: separately make rows in each sublayer of each layer of the check matrix to be corresponding to the P check nodes, where different rows correspond to different check nodes; receive data; and perform a corresponding operation in the layered normalized min-sum decoding algorithm on the data by using a corresponding row in each sublayer.

In some embodiments, the processing device is further configured to: determine an offset value, and adjust, based on the offset value, a sequence of using sublayers of a layer of the check matrix.

According to a third aspect, this application provides a computer program product. When the computer product is executed, the computer program product is used to perform the method according to any one of claims 1 to 5.

According to a fourth aspect, this application provides a computer-readable storage medium. The computer-readable storage medium stores instructions, and the instructions are used to perform the method according to any one of claims 1 to 5.

According to the foregoing technical solutions, it can be learned that embodiments of this application have the following advantages.

When the code word sequence whose digit quantity is n is received, the check matrix of an order m×n may be determined. The base matrix of the check matrix is a matrix of an order m_{b}×n_{b}, where m_{b} is equal to m/Z, n_{b} is equal to n/Z, and Z is the extension factor of the base matrix, both m and Z are positive integers, and Z is divisible by both m and n. Then, the L variable nodes are set based on the base matrix, where L is greater than or equal to the quantity of values not equal to −1 in the row with a maximum quantity of values not equal to −1 in the base matrix, and the value not equal to −1 in the base matrix represents a non-zero submatrix of an order Z×Z in the check matrix. Therefore, the layered normalized min-sum decoding algorithm may be performed by using a relatively small quantity of L variable nodes, and relatively few hardware resources are required, thereby effectively reducing costs.

### BRIEF DESCRIPTION OF DRAWINGS

FIG. 1A is a schematic diagram of a computer device in this application;

FIG. 1B is a schematic diagram of a process of interaction between a variable node and a check node;

FIG. 1C is a schematic diagram of a structure including a variable node and a check node;

FIG. 2A is a schematic diagram of a data processing method according to this application;

FIG. 2B is a schematic diagram of a preset matrix in a raptor-like structure;

FIG. 2C is a schematic diagram of a core matrix and an extended matrix in a preset matrix;

FIG. 2D is a schematic diagram of a core matrix;

FIG. 2E is a schematic diagram of a manner of obtaining a check matrix;

FIG. 2F is a schematic diagram of a conflict between reading and writing;

FIG. 2G is a schematic diagram of dividing one layer of a check matrix into three sublayer matrices; and

FIG. 3 is a schematic diagram of a decoder according to this application.

### DESCRIPTION OF EMBODIMENTS

Embodiments of this application provide a data processing method and a decoder, to decode a code word sequence.

In this application, terms such as “first”, “second”, “third”, and “fourth” (if present) in the specification, the claims, and the accompanying drawings are intended to distinguish between similar objects but do not necessarily indicate a specific order or sequence. It should be understood that the data used in such a way are interchangeable in proper cases so that embodiments described herein can be implemented in other orders than the order illustrated or described herein. In addition, the terms “include”, “contain” and any other variants mean to cover the non-exclusive inclusion, for example, a process, method, system, product, or device that includes a list of operations or units is not necessarily limited to those operations or units, but may include other operations or units not expressly listed or inherent to such a process, method, product, or device.

A QC-LDPC code is a common type of LDPC code, and a check matrix H of the QC-LDPC code includes a series of element submatrices of an order Z×Z where Z is referred to as an extension factor or dimension of the element submatrix. Each element submatrix is a cyclic right shift of a zero matrix or an identity matrix. Therefore, the element submatrix may also be represented by a value. For example, the zero matrix is represented as −1, the identity matrix is represented as 0, and a cyclic right shift of the identity matrix is represented as an offset of a right shift of the identity matrix.

A check matrix may also be represented by a matrix with a relatively small quantity of rows and columns, and this matrix is referred to as a base matrix. Therefore, it may be learned that a base matrix corresponding to a check matrix of an order m×n is a matrix of an order m_{b}×n_{b}, where m_{b} is equal to m/Z, and n_{b} is equal to n/Z. It is clearly that, Z is divisible by m and n.

The following check matrix is used as an example for description. It is assumed that the check matrix is:

$$( \begin{matrix}1 & 0 & 0 & 0 & 0 & 1 & 1 & 0 \\ 0 & 1 & 0 & 0 & 1 & 0 & 0 & 1 \\ 1 & 0 & 0 & 0 & 1 & 0 & 1 & 0 \\ 0 & 1 & 0 & 0 & 0 & 1 & 0 & 1\end{matrix} )$$

Assuming that an extension factor is equal to 2, a base matrix of the check matrix may be obtained:

$$( \begin{matrix}0 & - 1 & 1 & 0 \\ 0 & - 1 & 0 & 0\end{matrix} )$$

In this way, storage burden can be reduced.

For another example, a check matrix with a relatively large data amount may be represented as the following base matrix of an order 4×11, where an extension factor of the base matrix is equal to 256.

$$( \begin{matrix}23 & - 1 & 190 & 35 & 239 & 31 & 1 & 0 & - 1 & - 1 & - 1 \\ 142 & 155 & - 1 & 255 & - 1 & 28 & 0 & 0 & 0 & - 1 & - 1 \\ - 1 & 245 & 205 & 251 & 117 & - 1 & - 1 & - 1 & 0 & 0 & - 1 \\ 240 & 1 & 244 & - 1 & 144 & 1 & 1 & - 1 & - 1 & 0 & - 1\end{matrix} )$$

Each value in the base matrix may be extended to a matrix of an order 256×256. Therefore, only the base matrix may be stored without storing the check matrix. When being used, the matrix may be extended to the check matrix, which reduces storage burden and is very convenient.

After receiving a code word sequence, a receive end may decode the code word sequence by using a check matrix and a preset decoding algorithm, to obtain an information sequence. A common decoding algorithm includes a decoding algorithm based on layered normalized min-sum. The decoding algorithm based on layered normalized min-sum can effectively reduce hardware complexity and significantly reduce a quantity of decoding iterations, and therefore is widely used in decoder design.

When the decoding algorithm based on layered normalized min-sum is implemented, the check matrix is first vertically divided into several layers. For example, a submatrix that is of the check matrix and represented by a row of a base matrix is used as a layer of the check matrix. To be specific, it is assumed that the check matrix is a matrix of an order m×n, the base matrix of the check matrix is a matrix of an order m_{b}×n_{b}, and an extension factor is Z, that is, m_{b}=m/Z and n_{b}=n/Z, where Z is divisible by both m and n. This is equivalent to dividing the check matrix into m_{b} layers, and each layer is a matrix of an order Z×n_{b}. The foregoing described check matrix represented by the basis matrix of an order 4×11 may be divided into four layers, and each layer is a matrix of an order 256×11.

When decoding is performed, m_{b} rounds of decoding are separately performed, and a corresponding layer of the check matrix is used in each round. First, in a first round, the code word sequence is processed by using a first layer counted from top to down of the check matrix, to obtain a new sequence. Then, the new sequence is processed by using a second layer of the check matrix. By analogy, the code word sequence is iterated until a last layer of the check matrix is used, and a last obtained sequence is used as the information sequence.

Specifically, for a j^{th} layer of the check matrix (which may be represented by a j^{th} row of the base matrix, where a value of j is 0, 1, . . . , mb−1), the code word sequence is decoded by using the following three formulas:

$$\begin{matrix} {q}_{j , {n}_{j}} [ k ] = {λ}_{{n}_{j}} [ k ] - {r}_{j , {n}_{j}} [ k ] ( {n}_{j} ∈ N ( j ) ) & ( 1 ) \\ {new\_r}_{j , {n}_{j}} [ k ] = ( {\prod }_{{n}_{j}^{′} ∈ \{ V ( j ) ∖ {n}_{j} \}} sign ( {q}_{j , {n}_{j}^{′}} [ k ] ) ) \cdot ( {min}_{{n}_{j}^{′} ∈ \{ V ( j ) ∖ {n}_{j} \}} \{ \vert {q}_{j , {n}_{j}^{′}} [ k ] \vert \} \cdot α ) & ( 2 ) \\ {new\_λ}_{{n}_{j}} [ k ] = {q}_{j , {n}_{j}} [ k ] + {new\_r}_{j , {n}_{j}} [ k ] & ( 3 )\end{matrix}$$

In the foregoing formulas, nⱼ represents a sequence number of a column of the base matrix from left to right and has a value of 0, 1, . . . , n_{b}. In addition, N(j) represents a set of columns in which all values not equal to −1 in the j^{th} row of the base matrix are located, where for the check matrix represented by the base matrix of an order 4×11, N(j) includes 0, 2, 3, 4, 5, 6, and 7; k represents a sequence number of a row in a layer of the check matrix and has a value of 0, 1, . . . , Z−1; λ represents an input code word sequence, that is, a received code word sequence or a code word sequence obtained after iteration in a previous layer, where for the check matrix of an order m×n, λ may have n values; r represents a cyclic variable, which is used to be updated and iterated together with a code word sequence, to be used as an input value of a next layer, and also has n values, where an initial value of r may be set to 0; q represents an intermediate variable and is used to update and iterate λ in an operation (operations in the foregoing three formulas); α represents a correction factor and usually has a value of about 0.8; V(j)\nⱼ represents a set of values other than nⱼ in N(j); sign( ) represents a symbol function, to be specific, if a parameter of the symbol function is greater than 0, a value is 1; if a parameter is less than 0, a value is −1; or if a parameter is equal to 0, a value is 0; Π represents a cumulative product function; and min( ) represents a minimum function.

Through the foregoing three formulas, the code word sequence is iterated by using the check matrix to finally obtain the information sequence. To be specific, the code word sequence is first operated by using the first layer of the check matrix to obtain new_r_{j,n}_{ⱼ}[k] and new_Λₙ_{ⱼ}[k] Then, new_r_{j,n}_{ⱼ}[k] and new_Λₙ_{ⱼ}[k] are used as an input value to continue to be operated by continuing to use a next layer of the check matrix, until all layers of the check matrix are used. A finally obtained new code word sequence is used as the information sequence.

In this embodiment of this application, in terms of hardware, the code word sequence needs to be operated by a variable node and a check node by using the check matrix. The variable node is configured to perform formula (1), and then deliver an obtained result to the check node, so that the check node performs formula (2), and then returns an obtained result to the variable node. The variable node performs formula (3) to complete one iteration related to 2.

For better description, an architecture in this application is briefly described below.

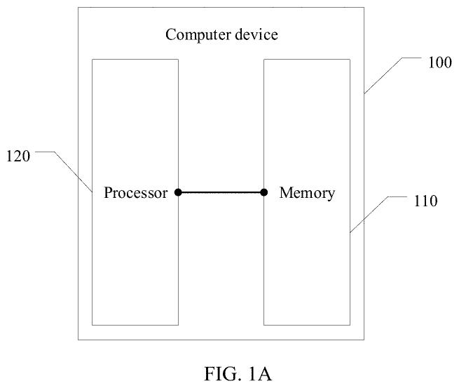

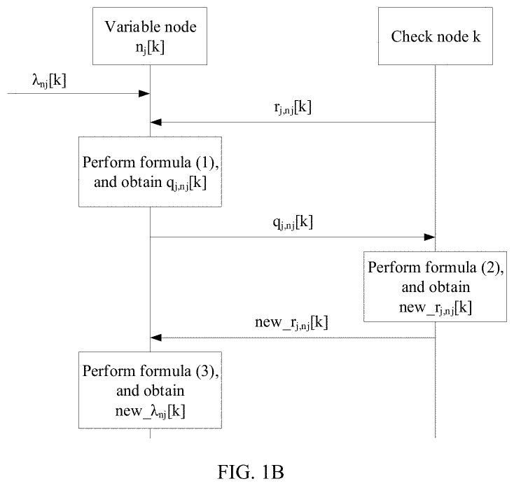

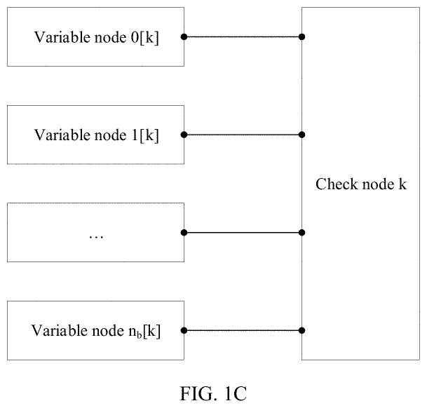

To cooperate with the foregoing operation process, refer to FIG. 1A, a computer device 100 needs to be used in this application. The computer device 100 includes a memory 110 and a processing device 120. The processing device 120 is configured to operate a code word sequence by using a check matrix. A plurality of variable nodes and a plurality of check nodes are disposed in the processing device 120. The variable node is configured to receive a code word sequence, and the check node is configured to store and provide a check matrix to the variable node.

As shown in FIG. 1B, the variable node is configured to: receive λₙⱼ[k] (whose initial value is a code word sequence), receive r_{j,nj}[k] (whose initial value may be all 0) sent by the check node, perform formula (1) to obtain q_{j,nj}[k] through calculation, and send q_{j,nj}[k] to the check node. After receiving q sent by the variable node, the check node performs formula (2) to obtain new_r_{j,nj}[k] through calculation, sends the new new_r_{j,nj}[k] to the variable node, and uses new_r as r used for calculation in a next layer. Finally, the variable node performs formula (3) to obtain new_λ_{j,nj}[k] through calculation, which is used as λ used for calculation in a next layer, that is, λ_{j+1,nj}[k].

To improve efficiency and reduce waste of nodes, a proper quantity of variable nodes and check nodes and a proper interaction manner need to be determined. Currently, a row-level parallel solution is mainly used to arrange variable nodes and check nodes.

In the row-level parallel solution, n_{b} variable nodes and Z check nodes are disposed, where the n_{b} variable nodes are in a one-to-one correspondence with n_{b} columns of a base matrix, the n_{b} variable nodes simultaneously perform formula (1), and send calculation results to a same check node. The Z check nodes are in a one-to-one correspondence with rows in each layer of a check matrix. The check node performs formula (2), and sends an obtained result to the variable node. The variable node performs formula (3) to obtain λ and r that are required in a next layer. Due to an orthogonal feature of QC-LDPC, Z structures shown in FIG. 1C can be simultaneously processed.

For a layer of the check matrix, columns of the base matrix are orthogonal, and therefore the n_{b} variable nodes simultaneously perform an operation. Because rows in a same layer of the check matrix are also orthogonal, the rows can be simultaneously used to perform operations for a same code word sequence by the rows, and the Z check nodes can be simultaneously performed and used, to improve efficiency.

The row-level parallel solution may provide calculation efficiency. However, if n_{b} is relatively large or Z is relatively large, relatively more hardware resources (variable nodes or check nodes) are required, resulting in relatively high costs. In particular, in a current 5G technology, a maximum used extension factor Z of a base matrix of a QC-LDPC code may be 384, and a maximum n_{b} may be 68. Therefore, it is difficult to be directly implemented based on the row-level parallel solution. In addition, the base matrix of the QC-LDPC code usually has a feature of sparsity. In many cases, a quantity of valid nodes in a row is far less than a total quantity of n_{b} nodes. Consequently, node resources are wasted in the row-level parallel solution.

Therefore, this application provides a data processing method and a system. When a code word sequence whose digit quantity is n is received, a check matrix of an order m×n may be determined. A base matrix of the check matrix is a matrix of an order m_{b}×_{b}, where m_{b} is equal to m/Z, n_{b} is equal to n/Z, and Z is an extension factor of the base matrix, both m and Z are positive integers, and Z is divisible by both m and n. Then, L variable nodes are set based on the base matrix, where L is greater than or equal to a quantity of values not equal to 1 in a row with a maximum quantity of values not equal to 1 in the base matrix, and the value not equal to 1 in the base matrix represents a non-zero submatrix of an order Z×Z in the check matrix. Therefore, a layered normalized min-sum decoding algorithm may be performed by using a relatively small quantity of L variable nodes, and relatively few hardware resources are required, thereby effectively reducing costs.

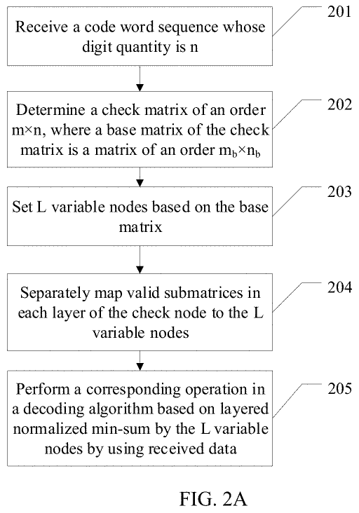

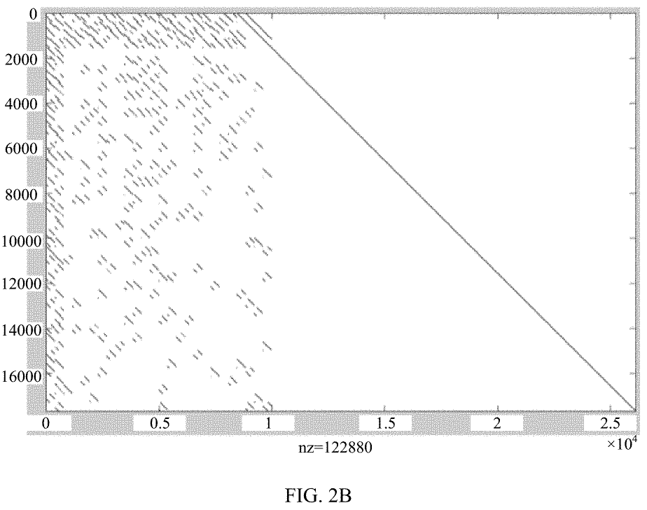

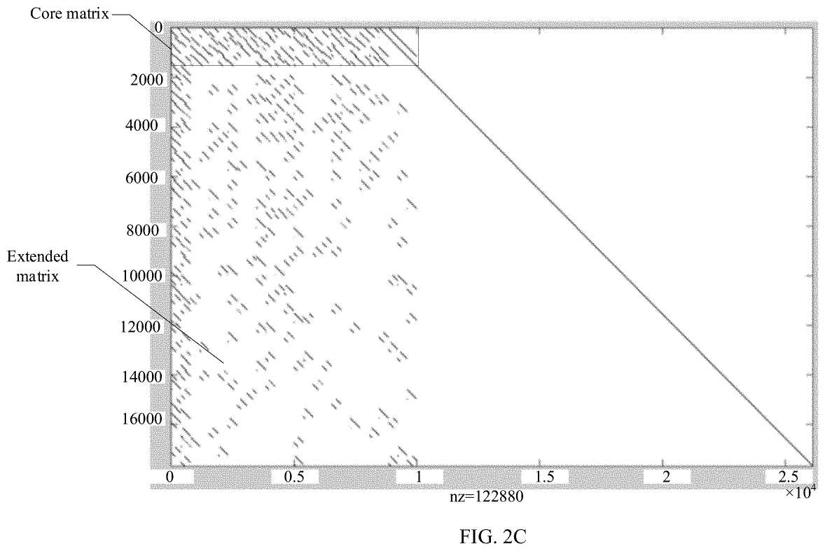

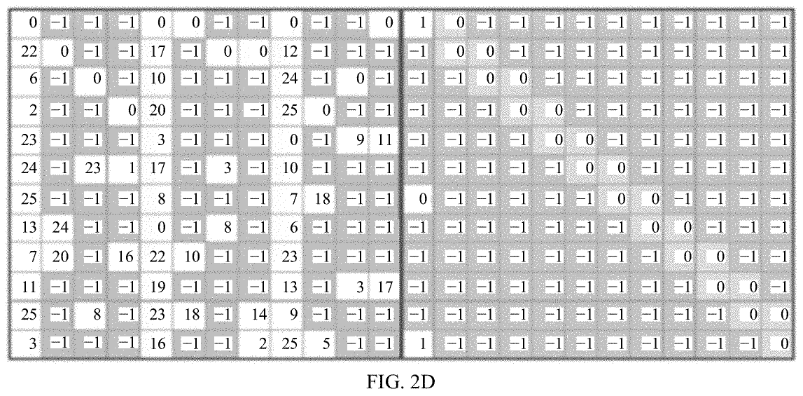

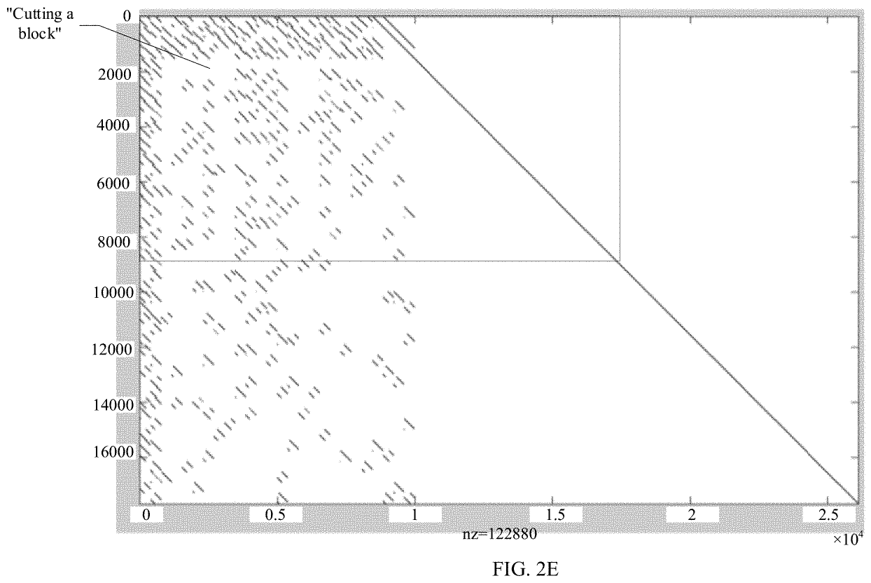

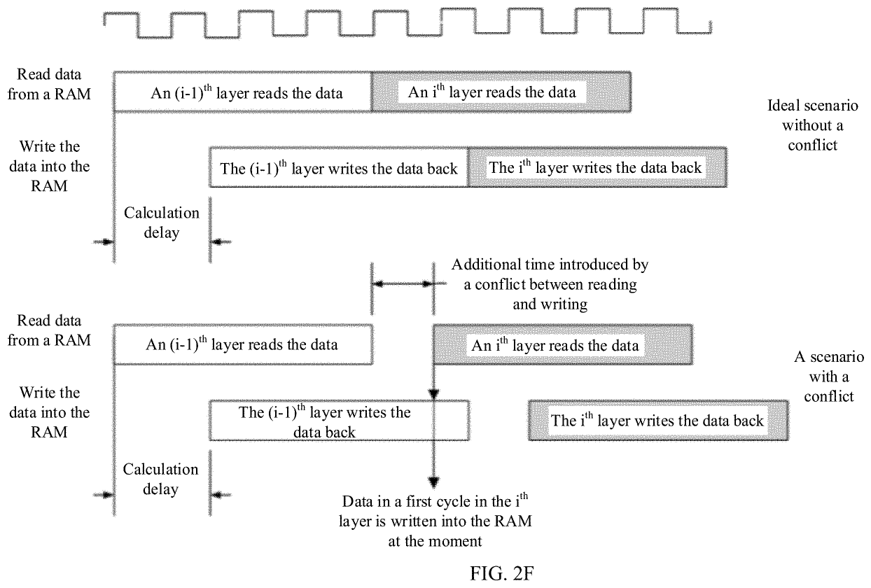

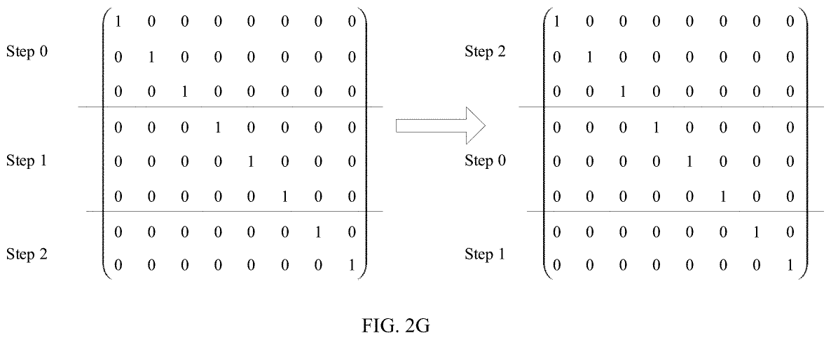

Specifically, refer to FIG. 2A. An embodiment of this application provides a data processing method, which includes the following operations.

201. Receive a code word sequence whose digit quantity is n, where n is a positive integer.

In a communication process, a transmit end performs channel encoding on an information sequence based on a check matrix to obtain a code word sequence. A receive end obtains the code word sequence, and transmits the obtained corresponding code word sequence through a channel, and may perform channel decoding on the code word sequence based on a check matrix or a base matrix by using a preset decoding algorithm, to obtain the information sequence included in the code word sequence.

For example, n is equal to 8, and the code word sequence has eight digits, which are respectively represented by λ as follows:

λ₀=3, λ₁=2, λ₂=−5, λ₃=−7, λ₄=4, λ₅=1, λ₆=−9, and λ₇=10

202. Determine a check matrix of an order m×n, where a base matrix of the check matrix is a matrix of an order m_{b}×n_{b}, m_{b} is equal to m/Z, n_{b} is equal to n/Z, Z is an extension factor of the base matrix, both m and Z are positive integers, and Z is divisible by both m and n.

In this embodiment of this application, the base matrix of an order m_{b}×n_{b} may be first determined based on n, Z, and a preset matrix having a raptor-like (raptor-like) structure, and then the base matrix is extended to obtain the check matrix of an order m×n.

It should be noted that the check matrix in a raptor-like structure includes two parts: a core matrix and an extended matrix. The core matrix may be in a form similar to a bidiagonal form in 802.11n, and supports a high bit rate. The extended matrix is in a form of single-column recheck and supports a low bit rate. Different bit rates can be flexibly obtained by selecting and using different quantities m_{b} of rows of the base matrix.

For example, FIG. 2B is a schematic diagram of a preset matrix in a raptor-like structure. Because the preset matrix has an excessively large data amount, the preset matrix is replaced by a slash in FIG. 2B. A part through which the slash passes represents 1 in the check matrix, and a remaining part represents 0. Each submatrix of an order Z×Z represents an offset of a zero matrix, an identity matrix, or an identity matrix, and indicates that the submatrix is an identity matrix or an offset of the identity submatrix.

As shown in FIG. 2C, a part in a black box at an upper left corner is the core matrix (as shown in FIG. 2D), and a remaining part is the extended matrix.

A preset matrix in a raptor-like structure is preset in each of the transmit end and the receive end. The transmit end determines a required base matrix from the preset matrix based on an information sequence that needs to be sent. This is similar to “cutting a block from the preset matrix” (as shown in FIG. 2E). Then a code word sequence is encoded by using a check matrix represented by the base matrix, to obtain a code word sequence and send the code word sequence to the receive end. After receiving the code word sequence whose digit quantity is n, the receive end determines n_{b} (n_{b}=n/Z) based on preset Z; then determines m_{b} based on n_{b} and the preset matrix, that is, “cutting” the base matrix of an order m_{b}×n_{b} from the preset matrix; and finally determines the check matrix represented by the base matrix. Then, the receive end extends the base matrix based on Z to obtain the check matrix.

203. Set L variable nodes based on the base matrix, where L is greater than or equal to a quantity of values not equal to −1 in a row with a maximum quantity of values not equal to −1 in the base matrix, and the value not equal to −1 in the base matrix represents a non-zero submatrix of an order Z×Z in the check matrix.

It should be noted that there may be three values in the base matrix: −1, 0, and an integer greater than 0, where −1 represents a zero matrix of an order Z×Z in the check matrix, 0 represents an identity matrix of an order Z×Z in the check matrix, and an integer greater than 0 represents an offset of an identity matrix of an order Z×Z. Therefore, the non-−1 value in the base matrix represents 0 or an integer greater than 0.

For example, Z is equal to 6, and an element submatrix of an order Z×Z is a matrix of an order 6×6. In this case, 1 represents a zero matrix;

$$( \begin{matrix}0 & 0 & 0 & 0 & 0 & 0 \\ 0 & 0 & 0 & 0 & 0 & 0 \\ 0 & 0 & 0 & 0 & 0 & 0 \\ 0 & 0 & 0 & 0 & 0 & 0 \\ 0 & 0 & 0 & 0 & 0 & 0 \\ 0 & 0 & 0 & 0 & 0 & 0\end{matrix} )$$

0 represents an identity matrix;

$$( \begin{matrix}1 & 0 & 0 & 0 & 0 & 0 \\ 0 & 1 & 0 & 0 & 0 & 0 \\ 0 & 0 & 1 & 0 & 0 & 0 \\ 0 & 0 & 0 & 1 & 0 & 0 \\ 0 & 0 & 0 & 0 & 1 & 0 \\ 0 & 0 & 0 & 0 & 0 & 1\end{matrix} )$$

1 indicates that the identity matrix is shifted by 1 bit to the right;

$$( \begin{matrix}0 & 1 & 0 & 0 & 0 & 0 \\ 0 & 0 & 1 & 0 & 0 & 0 \\ 0 & 0 & 0 & 1 & 0 & 0 \\ 0 & 0 & 0 & 0 & 1 & 0 \\ 0 & 0 & 0 & 0 & 0 & 1 \\ 1 & 0 & 0 & 0 & 0 & 0\end{matrix} )$$

2 indicates that the identity matrix is shifted by 2 bits to the right;

$$( \begin{matrix}0 & 0 & 1 & 0 & 0 & 0 \\ 0 & 0 & 0 & 1 & 0 & 0 \\ 0 & 0 & 0 & 0 & 1 & 0 \\ 0 & 0 & 0 & 0 & 0 & 1 \\ 1 & 0 & 0 & 0 & 0 & 0 \\ 0 & 1 & 0 & 0 & 0 & 0\end{matrix} )$$

and so on.

The base matrix has m_{b} rows, a row weight of each row is a quantity of values not equal to −1 in the row, and the quantity of values not equal to −1 in the row with a maximum quantity of values not equal to −1 in the rows of the base matrix is a maximum row weight of the base matrix. For example, for the following base matrix, a row weight of a zero^{th} row is 3, a row weight of a first row is 2. In this case, a row with a maximum quantity of values not equal to −1 is the zero^{th} row. The row weight of the row is 3, and therefore a maximum row weight of the base matrix is 3.

$${H}_{b} = ( \begin{matrix}0 & - 1 & 1 & 0 \\ 0 & - 1 & - 1 & 0\end{matrix} )$$

In this embodiment of this application, the L variable nodes may be disposed based on the maximum row weight of the base matrix, where L is greater than or equal to the maximum row weight of the base matrix. In some embodiments, L may be set to be equal to the maximum row weight of the base matrix.

203. Separately map valid submatrices in each layer of the check node to the L variable nodes, where different valid submatrices correspond to different variable node.

It should be noted that a layer of the check node is a submatrix represented by a row of the base matrix.

For example, for the following check matrix,

$$( \begin{matrix}1 & 0 & 0 & 0 & 0 & 0 & 1 & 0 \\ 0 & 1 & 0 & 0 & 0 & 0 & 0 & 1 \\ 1 & 0 & 0 & 0 & 0 & 1 & 1 & 0 \\ 0 & 1 & 0 & 0 & 1 & 0 & 0 & 1\end{matrix} )$$

an extension factor of a base matrix of the check matrix is 2, that is, the base matrix is:

$$( \begin{matrix}0 & - 1 & - 1 & 0 \\ 0 & - 1 & 1 & 0\end{matrix} )$$

In this case, a zero^{th} row of the base matrix represents a submatrix in a zero^{th} row layer of the check matrix, that is:

$$( \begin{matrix}1 & 0 & 0 & 0 & 0 & 0 & 1 & 0 \\ 0 & 1 & 0 & 0 & 0 & 0 & 0 & 1\end{matrix} )$$

The zero^{th} row of the base matrix represents a submatrix in the zero^{th} row layer of the check matrix, that is:

$$( \begin{matrix}1 & 0 & 0 & 0 & 0 & 1 & 1 & 0 \\ 0 & 1 & 0 & 0 & 1 & 0 & 0 & 1\end{matrix} )$$

In addition, the valid submatrix is a submatrix represented by the value not equal to −1 in the base matrix. A valid submatrix of the foregoing base matrix is a submatrix that is of the check matrix and that is represented by 0 and 1, and valid nodes in the zero^{th} layer of the check matrix are respectively as follows:

$$( \begin{matrix}1 & 0 \\ 0 & 1\end{matrix} ) ( \begin{matrix}1 & 0 \\ 0 & 1\end{matrix} )$$

Valid nodes in a first layer of the check matrix are respectively as follows:

$$( \begin{matrix}1 & 0 \\ 0 & 1\end{matrix} ) ( \begin{matrix}1 & 0 \\ 0 & 1\end{matrix} ) ( \begin{matrix}1 & 0 \\ 0 & 1\end{matrix} )$$

Because the maximum row weight of the check matrix is 3, L may be set to be equal to 3, to obtain a variable node 0, a variable node 1, and a variable node 2. Therefore, valid submatrices in each layer of the check node are mapped to the L variable nodes to obtain the following, where different valid submatrices correspond to different variable node.

$$( \begin{matrix}1 & 0 \\ 0 & 1\end{matrix} ) -> Variable node 0$$

$$( \begin{matrix}1 & 0 \\ 0 & 1\end{matrix} ) -> Variable node 1$$

The valid submatrices in each layer of the check node are mapped to the L variable nodes to obtain the following, where different valid submatrices correspond to different variable node.

$$( \begin{matrix}1 & 0 \\ 0 & 1\end{matrix} ) -> Variable node 0$$

$$( \begin{matrix}1 & 0 \\ 0 & 1\end{matrix} ) -> Variable node 1$$

$$( \begin{matrix}1 & 0 \\ 0 & 1\end{matrix} ) -> Variable node 2$$

204. Send, to each of the L mapped variable nodes, data corresponding to each valid submatrix in each layer of the check matrix.

205. Perform a corresponding operation in the layered normalized min-sum decoding algorithm by the L variable nodes by using the received data (e.g., the data that was sent).

It should be noted that this embodiment of this application is implemented by the layered normalized min-sum decoding algorithm. Specifically, for a j^{th} layer of the check matrix (which may be represented by a j^{th} row of the base matrix, where a value of j is 0, 1, . . . , mb−1), the code word sequence is decoded by using the following three formulas:

$$\begin{matrix} {q}_{j , {n}_{j}} [ k ] = {λ}_{{n}_{j}} [ k ] - {r}_{j , {n}_{j}} [ k ] ( {n}_{j} ∈ N ( j ) ) & ( 1 ) \\ {new\_r}_{j , {n}_{j}} [ k ] = ( {\prod }_{{n}_{j}^{′} ∈ \{ V ( j ) ∖ {n}_{j} \}} sign ( {q}_{j , {n}_{j}^{′}} [ k ] ) ) \cdot ( {min}_{{n}_{j}^{′} ∈ \{ V ( j ) ∖ {n}_{j} \}} \{ \vert {q}_{j , {n}_{j}^{′}} [ k ] \vert \} \cdot α ) & ( 2 ) \\ {new\_λ}_{{n}_{j}} [ k ] = {q}_{j , {n}_{j}} [ k ] + {new\_r}_{j , {n}_{j}} [ k ] & ( 3 )\end{matrix}$$

In the foregoing formulas, nⱼ represents a sequence number of a column of the base matrix from left to right and has a value of 0, 1, . . . , n_{b}. In addition, N(j) represents a set of columns in which all values not equal to −1 in the j^{th} row of the base matrix are located, where for the check matrix represented by the base matrix of an order 4×11, N(j) includes 0, 2, 3, 4, 5, 6, and 7; k represents a sequence number of a row in a layer of the check matrix and has a value of 0, 1, . . . , Z−1; λ represents an input code word sequence, that is, a received code word sequence or a code word sequence obtained after iteration in a previous layer, where for the check matrix of an order m×n, λ may have n values; r represents a cyclic variable, which is used to be updated and iterated together with a code word sequence, to be used as an input value of a next layer, and also has n values, where an initial value of r may be set to 0; q represents an intermediate variable and is used to update and iterate λ in an operation (operations in the foregoing three formulas); α represents a correction factor and usually has a value of about 0.8; V(j)\nⱼ represents a set of values other than nⱼ in N(j); sign( ) represents a symbol function, to be specific, if a parameter of the symbol function is greater than 0, a value is 1; if a parameter is less than 0, a value is −1; or if a parameter is equal to 0, a value is 0; Π represents a cumulative product function; and min( ) represents a minimum function.

Through the foregoing three formulas, the code word sequence is iterated by using the check matrix to finally obtain the information sequence. To be specific, the code word sequence is first operated by using the first layer of the check matrix to obtain new_r_{j,n}_{ⱼ}[k] and new_Λₙ_{ⱼ}[k]; then new_r_{j,n}_{ⱼ}[k] and new_Λₙ_{ⱼ}[k_{]} are used as an input value to continue to be operated by continuing to use a next layer of the check matrix, until all layers of the check matrix are used; and a finally obtained new code word sequence is used as the information sequence.

In this embodiment of this application, in terms of hardware, the code word sequence may be operated by a variable node and a check node by using the check matrix. The variable node is configured to perform formula (1), and then deliver an obtained result to the check node, so that the check node performs formula (2), and then returns an obtained result to the variable node. The variable node performs formula (3) to complete one iteration related to 2.

In this embodiment of this application, because mapping of the valid submatrices in each layer of the check node to the L variable nodes is determined, there is no need to dispose n_{b} variable nodes, and only L variable nodes need to be disposed, to complete calculation of the code word sequence.

The following uses an example for description.

It is assumed that a quantity of values of λ is 8, that is, a code word sequence of eight digits is received, and it is assumed that λ₀=3, λ₁=2, λ₂=−5, λ₃=−7, λ₄=4, λ₅=1, λ₆=−9, and λ₇=10.

It is assumed that the check matrix is:

$$H = ( \begin{matrix}1 & 0 & 0 & 0 & 0 & 1 & 1 & 0 \\ 0 & 1 & 0 & 0 & 1 & 0 & 0 & 1 \\ 1 & 0 & 0 & 0 & 1 & 0 & 1 & 0 \\ 0 & 1 & 0 & 0 & 0 & 1 & 0 & 1\end{matrix} )$$

A base matrix whose extension factor of the check matrix is 2 is:

$${H}_{b} = ( \begin{matrix}0 & - 1 & 1 & 0 \\ 0 & - 1 & 0 & 0\end{matrix} )$$

An operation processing is performed on the code word sequence by using a first layer of the check matrix (the check matrix includes two layers in total, and each layer includes two rows), and an input value is the received code word sequence. It may be learned that λₙⱼ[k] is a k^{th} row that is of the check matrix and that is represented by an Nⱼ^{th} row of the base matrix. To be specific, when j=0, values of nⱼ are respectively 0, 2, and 3, that is, a code word sequence that may be processed is λ₀[0]=λ₀, λ₂[0]=λ₅, λ₃[0]=λ₆, λ₀[1]=λ₁, λ₂[1]=λ₄, λ₃[1]=λ₇, and so on. After operation processing is performed on λₙⱼ[k], a new sequence is obtained. The new sequence is used as an input value of next layer, that is, a similar operation is performed when j=1.

In this embodiment of this application, there is no need to dispose four variable nodes. A maximum row weight (that is, 3) of the base matrix continues to be determined, and then it is determined that only variable nodes whose quantity is greater than or equal to the maximum row weight need to be disposed, that is, three variable nodes (which are respectively a variable node 0, a variable node 1, and a variable node 2) can be disposed. Then mapping from each valid node of the check matrix to each variable node is established, for example, in the zero^{th} of the check node, the mapping is as follows:

$$( \begin{matrix}1 & 0 \\ 0 & 1\end{matrix} ) -> Variable node 0$$

$$( \begin{matrix}0 & 1 \\ 1 & 0\end{matrix} ) -> Variable node 1$$

$$( \begin{matrix}1 & 0 \\ 0 & 1\end{matrix} ) -> Variable node 2$$

In the first layer of the check node, the mapping is as follows:

$$( \begin{matrix}1 & 0 \\ 0 & 1\end{matrix} ) -> Variable node 0$$

$$( \begin{matrix}1 & 0 \\ 0 & 1\end{matrix} ) -> Variable node 1$$

$$( \begin{matrix}1 & 0 \\ 0 & 1\end{matrix} ) -> Variable node 2$$

The variable node is used to operate formulas (1) and (3), and the check node is used to operate formula (2).

First, for λ₀=3, λ₁=2, λ₂=−5, λ₃=−7, λ₄=4, λ₅=1, λ₆=−9, and λ₇=10, it is assumed that an initial value of r is 0, that is, r_{j,nj}[0] is 0. In this case, it may be determined according to formula (1) that λ that may be calculated is λ₀, λ₅, and λ₆, and then λ₀ is sent to the variable node 0, λ₅ is sent to the variable node 1, and λ₆ is sent to the variable node 2, to obtain the following through calculation:

q_{0,0}[0]=λ₀[0]=λ₀=3

q_{0,2}[0]=λ₂[0]=λ₅=1

q_{0,3}[0]=λ₃[0]=λ₆=−9 Formula (1):

Then, q_{0,0}, q_{0,2}, and q_{0,3} are sent to the check node, and the check node performs formula (2):

new_r_{0,0}[0]=(1·−1)·min(1,9)=−1

new_r_{0,2}[0]=(1·−1)·min(3,9)=−3

new_r_{0,3}[0]=(1·1)·min(3,1)=1 Formula (2):

After new r_{0,0}[0], new_r_{0,2}[0], and new_r_{0,3}[0] are obtained, new_r_{0,0}[0], new_r_{0,2}[0], and new_r_{0,3}[0] are sent to the variable node, so that the variable node performs formula (3):

new_λ₀[0]=q_{0,0}[0]+new_r_{0,0}[0]=3−1=2

new_λ₂[0]=q_{0,2}[0]+new_r_{0,2}[0]=1−3=−2

new_λ₃[0]=q_{0,3}[0]+new_r_{0,3}[0]=−9+1=−8 Formula (3):

Therefore, new_λ_{0,0}[0], new_λ_{0,2}[0], and new_λ_{0,3}[0] are obtained, and the remaining λ₁, λ₂, λ₃, λ₄, and λ₇ all have no change.

Similarly, the foregoing three formulas may continue to be used by using a row k=1 to obtain:

q_{0,0}[1]=λ₀[1]=λ₁=2

q_{0,2}[1]=λ₂[1]=λ₄=4

q_{0,3}[1]=λ3[1]=λ₇=10 Formula (1):

new_r_{0,0}[1]=(1·−1)·min(1,9)=−1

new_r_{0,2}[1]=(1·−1)·min(3,9)=−3

new_r_{0,3}[1]=(1·1)·min(3,1)=1 Formula (2):

new_λ₀[1]=q_{0,0}[1]+new_r_{0,0}[1]=3−1=2

new_λ₂[1]=q_{0,2}[1]+new_r_{0,2}[1]=1−3=−2

new_λ₃[1]=q_{0,3}[1]+new_r_{0,3}[1]=−9+1=−8 Formula (3):

After the foregoing operation, λ₁, λ₄, and λ₇ also change.

One layer of the check matrix has two rows, and after the code word sequence is operated by the two rows, an obtained new λ is:

λ₀=2, λ₁=2, λ₂=−5, λ₃−7, λ₄=−2, λ₅=−2, λ₆=−8, and λ₇=−8

Then, these sequences are delivered to a next layer as input values. Four variable nodes process these sequences in a same manner, and an obtained latest sequence is used as the information sequence.

After calculation performed by using a layer j=1 in the check matrix, the following is obtained:

q_{1,0}[0]=λ₀[0]=λ₀=2

q_{1,2}[0]=λ₂[0]=λ₄−=2

q_{1,3}[0]=λ₃[0]=λ₆=−8 Formula (I):

new_r_{1,0}[0]=(−1·−1)·min(2,8)=2

new_r_{1,2}[0]=(1·−1)·min(2,8)=−2

new_r_{1,3}[0]=(1·−1)·min(2,2)=−2 Formula (2):

new_λ₀[0]=q_{1,0}[0]+new_r_{1,0}[0]=2−2=0

new_λ₂[0]=q_{1,2}[0]+new_r_{1,2}[0]=2−(−2)=0

new_λ₃[0]=q_{1,3}[0]+new_r_{1,3}[0]=−8−(−2)=−6 Formula (3):

Similarly, the foregoing three formulas may continue to be used by using a row k=1 to obtain:

q_{1,0}[1]=λ₀[1]=λ₀32 2

q_{1,2}[1]=λ₂[1]=λ₅=−2

q_{1,3}[1]=λ₃[1]=λ₇=−8 Formula (1):

new_r_{1,0}[1]=(−1·−1)·min(2,8)=2

new_r_{1,2}[1]=(1·−1)·min(2,8)=2

new_r_{1,3}[1]=(1·−1)·min(2,2)=2 Formula (2):

new_λ₀[1]=q_{1,0}[1]+new_r_{1,0}[1]=2−2=0

new_λ₂[1]=q_{1,2}[1]+new_r_{1,2}[1]=−2−(−2)=0

new_λ₃[1]=q_{1,3}[1]+new_r_{1,3}[1]=−8−(−2)=−6 Formula (3):

Therefore, a last information sequence is (0, 0, 0, −7, 0, −2, −6, −6).

It should be noted that in the foregoing example, Z check nodes are required. For each layer of the check matrix, the Z check nodes are simultaneously performed to improve running efficiency. In some embodiments, P check nodes may be disposed, where P is a positive integer less than Z, each layer of the check matrix is divided into ceiling (Z/P) sublayers, ceiling( ) is a rounding up function, and each sublayer includes rows not exceeding P rows of the check matrix. When the layered normalized min-sum decoding algorithm is performed, rows in each sublayer of each layer of the check matrix separately correspond to the P check nodes, where different rows correspond to different check nodes. After receiving data, the P check nodes performs a corresponding operation in the layered normalized min-sum decoding algorithm on the data by using a corresponding row in each sublayer.

For example, a layer of the check matrix has eight rows, that is, the extension factor Z of the base matrix is equal to 8. An identity matrix of the check matrix is used as an instance of a valid submatrix.

$$( \begin{matrix}1 & 0 & 0 & 0 & 0 & 0 & 0 & 0 \\ 0 & 1 & 0 & 0 & 0 & 0 & 0 & 0 \\ 0 & 0 & 1 & 0 & 0 & 0 & 0 & 0 \\ 0 & 0 & 0 & 1 & 0 & 0 & 0 & 0 \\ 0 & 0 & 0 & 0 & 1 & 0 & 0 & 0 \\ 0 & 0 & 0 & 0 & 0 & 1 & 0 & 0 \\ 0 & 0 & 0 & 0 & 0 & 0 & 1 & 0 \\ 0 & 0 & 0 & 0 & 0 & 0 & 0 & 1\end{matrix} )$$

Each layer of the check matrix is divided into ceiling (Z/P) sublayers, where ceiling( ) is a rounding up function, and each sublayer includes rows not exceeding P rows of the check matrix. Assuming that P=3, that is, ceiling (Z/P)=3, the following is obtained:

$$( \frac{\begin{matrix}1 & 0 & 0 & 0 & 0 & 0 & 0 & 0 \\ 0 & 1 & 0 & 0 & 0 & 0 & 0 & 0 \\ 0 & 0 & 1 & 0 & 0 & 0 & 0 & 0\end{matrix}}{\frac{\begin{matrix}0 & 0 & 0 & 1 & 0 & 0 & 0 & 0 \\ 0 & 0 & 0 & 0 & 1 & 0 & 0 & 0 \\ 0 & 0 & 0 & 0 & 0 & 1 & 0 & 0\end{matrix}}{\begin{matrix}0 & 0 & 0 & 0 & 0 & 0 & 1 & 0 \\ 0 & 0 & 0 & 0 & 0 & 0 & 0 & 1\end{matrix}}} )$$

In this way, only P (that is, three) check nodes need to be disposed, which respectively perform and use operations of the foregoing sublayers 0, 1, and 2.

It should be noted that in a layered decoding algorithm, calculation of each layer depends on a calculation result of an upper layer. Because processing of a calculation unit (a variable node or a check node) has a delay, if data that is to be read and that is processed in an i^{th} layer is not written into a RAM after being processed in an (i−1)^{th} layer, a conflict between reading and writing exists. In this case, additional waiting time may be introduced, which affects a throughput rate of a decoder, as shown in FIG. 2F.

A conflict between processing in an upper layer and processing in a lower layer is related to quasi-cyclic matrix shift values of the two layers. Based on a quasi-cyclic feature of a QC-LDPC code, Z check nodes in a row of the base matrix are orthogonal, processing of the Z nodes has no sequence, and therefore results are the same. Same offset value transformation is added to all values not equal to −1 in a row of the base matrix, so that a sequence of the check nodes can be adjusted.

For example, as shown in FIG. 2G, an operation sequence of the foregoing three sublayer matrices obtained through division is adjusted. A proper offset value is found to perform sequence transformation shown below on the matrix. When a transformed matrix is used, impact of a conflict between reading and writing on a throughput rate of a decoder can be alleviated to an extent.

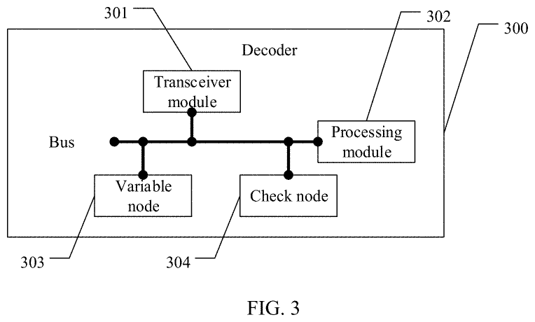

Refer to FIG. 3. This application provides a decoder 300. The decoder 300 uses a decoding algorithm based on layered normalized min-sum and includes: a transceiver module 301, a processing device 302, and L variable nodes 303.

The transceiver module 301 is configured to receive a code word sequence whose digit quantity is n, where n is a positive integer.

The processing device 302 is configured to determine a check matrix of an order m×n, where a base matrix of the check matrix is a matrix of an order m_{b}×n_{b}, m_{b} is equal to m/Z, n_{b} is equal to n/Z, Z is an extension factor of the base matrix, both m and Z are positive integers, and Z is divisible by both m and n.

The processing device 302 is further configured to set L variable nodes based on the base matrix, where L is greater than or equal to a quantity of values not equal to −1 in a row with a maximum quantity of values not equal to −1 in the base matrix, and the value not equal to −1 in the base matrix represents a non-zero submatrix of an order Z×Z in the check matrix.

The processing device 302 is further configured to: separately map valid submatrices in each layer of the check node to the L variable nodes, where different valid submatrices are mapped to different variable nodes, the valid submatrix is a submatrix represented by the value not equal to −1 in the base matrix, and a layer of the check node is a submatrix represented by a row of the base matrix. The processing device is further configured to send, to each of the L mapped variable nodes, data corresponding to each valid submatrix in each layer of the check matrix.

The L variable nodes 303 are configured to perform a corresponding operation in the layered normalized min-sum decoding algorithm by using the received data.

In some embodiments, the processing device 302 is configured to:

determine the base matrix of an order m_{b}×n_{b} based on n, Z, and a preset matrix having a raptor-like structure; and

extend the base matrix to obtain the check matrix of an order m×n.

In some embodiments, the processing device 302 is further configured to:

set P check nodes, where P is a positive integer less than Z, each layer of the check matrix is divided into ceiling (Z/P) sublayers, ceiling( ) is a rounding up function, and each sublayer includes rows not exceeding P rows of the check matrix.

The decoder further includes: P check nodes 304, configured to: separately make rows in each sublayer of each layer of the check matrix to be corresponding to the P check nodes, where different rows correspond to different check nodes; receive data; and perform a corresponding operation in the layered normalized min-sum decoding algorithm on the data by using a corresponding row in each sublayer.

In some embodiments, the processing device 302 is further configured to:

determine an offset value, and adjust, based on the offset value, a sequence of using sublayers of a layer of the check matrix.

All or some of the foregoing embodiments may be implemented by using software, hardware, firmware, or any combination thereof. When software is used to implement embodiments, the embodiments may be implemented completely or partially in a form of a computer program product.

The computer program product includes one or more computer instructions. When the computer program instructions are loaded and executed on a computer, all or some of the procedures or the functions according to embodiments of the present disclosure are generated. The computer may be a general-purpose computer, a dedicated computer, a computer network, or another programmable apparatus. The computer instructions may be stored in a computer-readable storage medium or may be transmitted from a computer-readable storage medium to another computer-readable storage medium. For example, the computer instructions may be transmitted from a website, computer, server, or data center to another website, computer, server, or data center in a wired (for example, a coaxial cable, an optical fiber, or a digital subscriber line (DSL)) or wireless (for example, infrared, radio, or microwave) manner. The computer-readable storage medium may be any usable medium accessible by the computer, or a data storage device, such as a server or a data center, integrating one or more usable media. The usable medium may be a magnetic medium (for example, a floppy disk, a hard disk, or a magnetic tape), an optical medium (for example, a DVD), a semiconductor medium (for example, a solid state disk (SSD)), or the like.

It may be clearly understood by a person skilled in the art that, for purpose of convenient and brief description, for a detailed working process of the foregoing system, apparatus, and unit, refer to a corresponding process in the foregoing method embodiments. Details are not described herein again.

In several embodiments provided in this application, it should be understood that the disclosed systems, apparatuses, and methods may be implemented in other manners. For example, the described apparatus embodiments are merely examples. For example, the unit division is merely logical function division and may be other division during actual implementation. For example, a plurality of units or components may be combined or integrated into another system, or some features may be ignored or not performed. In addition, the displayed or discussed mutual couplings or direct couplings or communication connections may be implemented through some interfaces. The indirect couplings or communication connections between the apparatuses or units may be implemented in electronic, mechanical, or other forms.

The units described as separate parts may or may not be physically separate, and parts displayed as units may or may not be physical units, may be located at one position, or may be distributed on a plurality of network units. Some or all of the units may be selected based on actual requirements to achieve the objectives of the solutions of embodiments.

In addition, functional units in embodiments of this application may be integrated into one processing unit, or each of the units may exist alone physically, or two or more units are integrated into one unit. The integrated unit may be implemented in a form of hardware, or may be implemented in a form of a software function unit.

When the integrated unit is implemented in the form of a software function unit and sold or used as an independent product, the integrated unit may be stored in a computer-readable storage medium. Based on such an understanding, the technical solutions of this application essentially, or the part contributing to the conventional technology, or all or some of the technical solutions may be implemented in the form of a software product. The computer software product is stored in a storage medium and includes several instructions for instructing a computer device (which may be a personal computer, a server, or a network device) to perform all or some of the operations of the methods described in embodiments of this application. The storage medium includes any medium that can store program code, such as a USB flash drive, a removable hard disk, a read-only memory (ROM), a random access memory (RAM), a magnetic disk, or an optical disc.

The foregoing embodiments are merely intended for describing the technical solutions of this application, but not for limiting this application. Although this application is described in detail with reference to the foregoing embodiments, persons of ordinary skill in the art should understand that they may still make modifications to the technical solutions described in the foregoing embodiments or make equivalent replacements to some technical features thereof, without departing from the spirit and scope of the technical solutions of embodiments of this application.

What is claimed is:

1. A computer-implemented method comprising:
receiving a code word sequence whose digit quantity is n, wherein n is a positive integer;
determining a check matrix of an order m×n, wherein a base matrix of the check matrix is a matrix of an order m_{b}×n_{b}, m_{b} is equal to m/Z, n_{b} is equal to n/Z, Z is an extension factor of the base matrix, both m and Z are positive integers, and Z is divisible by both m and n;
setting L variable nodes based on the base matrix, wherein L is greater than or equal to a quantity of values not equal to −1 in a row with a maximum quantity of values not equal to −1 in the base matrix, and each of the values not equal to −1 in the base matrix represents a non-zero submatrix of an order Z×Z in the check matrix;
separately mapping valid submatrices in each layer of a check node to the L variable nodes, wherein different ones of the valid submatrices are mapped to different ones of the L variable nodes, wherein each of the valid submatrices is a submatrix represented by one of the values not equal to −1 in the base matrix, and wherein the layer of the check node is a submatrix represented by a row of the base matrix;
sending, to each of the L variable nodes that were mapped, data corresponding to each valid submatrix in each layer of the check matrix; and
performing a corresponding operation in a layered normalized min-sum decoding algorithm by the L variable nodes using the data that was sent.

2. The method according to claim 1, wherein L is equal to the quantity of values not equal to 1 in the row with a maximum quantity of values not equal to −1 in the base matrix.

3. The method according to claim 1, wherein the determining the check matrix of the order m×n comprises:
determining the base matrix of the order m_{b}×n_{b} based on n, Z, and a preset matrix having a raptor-like structure; and
extending the base matrix to obtain the check matrix of the order m×n.

4. The method according to claim 1, wherein the method further comprises:
setting P check nodes, wherein P is a positive integer less than Z, each layer of the check matrix is divided into ceiling (Z/P) sublayers, ceiling( ) is a rounding up function, and each of the sublayers comprises rows not exceeding P rows of the check matrix; and
separately making rows in each sublayer of each layer of the check matrix to be corresponding to the P check nodes, wherein different rows correspond to different check nodes; receiving data by using the P check nodes; and performing a corresponding operation in the layered normalized min-sum decoding algorithm on the data by using a corresponding row in each sublayer.

5. The method according to claim 4, further comprising:
after the setting the P check nodes, determining an offset value, and adjusting, based on the offset value, a sequence of using sublayers of a layer of the check matrix.

6. A decoder, comprising:
a processor, and
a memory coupled to the processor, the memory comprising instructions that, when executed by the processor, cause the decoder to:
receive a code word sequence whose digit quantity is n, wherein n is a positive integer;
determine a check matrix of an order m×n, wherein a base matrix of the check matrix is a matrix of an order m_{b}×n_{b}, m_{b} is equal to m/Z, n_{b} is equal to n/Z, Z is an extension factor of the base matrix, both m and Z are positive integers, and Z is divisible by both m and n;
set L variable nodes based on the base matrix, wherein L is greater than or equal to a quantity of values not equal to −1 in a row with a maximum quantity of values not equal to −1 in the base matrix, and each of the values not equal to −1 in the base matrix represents a non-zero submatrix of an order Z×Z in the check matrix;
separately mapping valid submatrices in each layer of a check node to the L variable nodes, wherein different one of the valid submatrices are mapped to different ones of the L variable nodes, wherein each of the valid submatrices is a submatrix represented by one of the values not equal to 1 in the base matrix, and wherein the layer of the check node is a submatrix represented by a row of the base matrix;
send, to each of the L variable nodes that were mapped, data corresponding to each valid submatrix in each layer of the check matrix; and
perform a corresponding operation in a layered normalized min-sum decoding algorithm using the data that was sent.

7. The decoder according to claim 6, wherein the instructions, when executed by the processor, further cause the decoder to:
determine the base matrix of the order m_{b}×n_{b} based on n, Z, and a preset matrix having a raptor-like structure; and
extend the base matrix to obtain the check matrix of the order m×n.

8. The decoder according to claim 6, wherein the instructions, when executed by the processor, further cause the decoder to:
set P check nodes, wherein P is a positive integer less than Z, each layer of the check matrix is divided into ceiling (Z/P) sublayers, ceiling( ) is a rounding up function, and each of the sublayers comprises rows not exceeding P rows of the check matrix;
wherein the P check nodes, configured to: separately make rows in each sublayer of each layer of the check matrix to be corresponding to the P check nodes, wherein different rows correspond to different check nodes; receive data; and perform a corresponding operation in the layered normalized min-sum decoding algorithm on the data by using a corresponding row in each sublayer.

9. The decoder according to claim 8, wherein the instructions, when executed by the processor, further cause the decoder to:
determine an offset value, and adjust, based on the offset value, a sequence of using sublayers of a layer of the check matrix.

10. A computer-readable storage medium, wherein the computer-readable storage medium stores instructions, and the instructions, when executed by a processing device, cause the processing device to perform operations comprising:
receiving a code word sequence whose digit quantity is n, wherein n is a positive integer;
determining a check matrix of an order m×n, wherein a base matrix of the check matrix is a matrix of an order m_{b}×n_{b}, m_{b} is equal to m/Z, n_{b} is equal to n/Z, Z is an extension factor of the base matrix, both m and Z are positive integers, and Z is divisible by both m and n;
setting L variable nodes based on the base matrix, wherein L is greater than or equal to a quantity of values not equal to −1 in a row with a maximum quantity of values not equal to −1 in the base matrix, and each of the values not equal to −1 in the base matrix represents a non-zero submatrix of an order Z×Z in the check matrix;
separately mapping valid submatrices in each layer of a check node to the L variable nodes, wherein different ones of the valid submatrices are mapped to different ones of the L variable nodes, wherein each of the valid submatrices is a submatrix represented by one of the values not equal to −1 in the base matrix, and wherein the layer of the check node is a submatrix represented by a row of the base matrix;
sending, to each of the L variable nodes that were mapped, data corresponding to each valid submatrix in each layer of the check matrix; and
performing a corresponding operation in a layered normalized min-sum decoding algorithm by the L variable nodes using the data that was sent.

11. The computer-readable storage medium according to claim 10, wherein L is equal to the quantity of values not equal to −1 in the row with a maximum quantity of values not equal to −1 in the base matrix.

12. The computer-readable storage medium according to claim 10, wherein the determining the check matrix of the order m×n comprises:
determining the base matrix of the order m_{b}×n_{b} based on n, Z, and a preset matrix having a raptor-like structure; and
extending the base matrix to obtain the check matrix of the order m×n.

13. The computer-readable storage medium according to claim 10, wherein the operations further comprise:
setting P check nodes, wherein P is a positive integer less than Z, each layer of the check matrix is divided into ceiling (Z/P) sublayers, ceiling( ) is a rounding up function, and each of the sublayers comprises rows not exceeding P rows of the check matrix; and
separately making rows in each sublayer of each layer of the check matrix to be corresponding to the P check nodes, wherein different rows correspond to different check nodes; receiving data by using the P check nodes; and performing a corresponding operation in the layered normalized min-sum decoding algorithm on the data by using a corresponding row in each sublayer.

14. The computer-readable storage medium according to claim 13, wherein the operations further comprise:
after the setting P check nodes, determining an offset value, and adjusting, based on the offset value, a sequence of using sublayers of a layer of the check matrix.

15. The computer-readable storage medium according to claim 10, wherein the performing the corresponding operation in the layered normalized min-sum decoding algorithm by the L variable generates an information sequence from the code word sequence.
